(19) United States
(12) Patent Application Publication
(10) Pub. No.: US 2010/0021655 A1
(43) Pub. Date: Jan. 28, 2010

(54) PLASMA ELECTRODE

(76) Inventors: Robert P. Haley, JR., Midland, MI (US); Mark J. Semer, Beaverton, MI (US)

Correspondence Address: The Dow Chemical Company, Intellectual Property Section, P.O. Box 1967, Midland, MI, 48641-1967, US

(21) Appl. No.: 12/441,852

(22) PCT Filed: Sep. 21, 2007
(86) PCT No.: PCT/US07/20512

§ 371 Date: Mar. 18, 2009

Related U.S. Application Data
(60) Provisional application No. 60/849,157, filed on Oct. 3, 2006.

(51) Int. Cl. H01J 37/32; C23C 16/513

(52) U.S. Cl. 427/569; 118/723 E

(57) ABSTRACT

An improved electrode (44) useful for modifying a substrate using corona or plasma treatment or coating a substrate using plasma enhanced chemical vapor deposition under atmospheric or near atmospheric pressure conditions, the electrode comprising a body (10) defining at least a first cavity therein, the body having at least one inlet passageway (12) therein in gaseous communication with the first cavity (11) so that a gas mixture can be flowed into the first cavity by way of the at least one inlet passageway (12), the electrode having at least one outlet passageway (43) therein in gaseous communication with the first cavity so that a gas that is flowed into the first cavity can flow out of the cavity by way of the at least one outlet passageway. The improvement of the instant invention requires that the at least one outlet passageway be a slot (43) and that the body (10) include at least a first removable portion thereof, one edge of the first removable portion (30, 31) defining one side of the at least one outlet passageway (43).

### CROSS REFERENCE STATEMENT

This application claims the benefit of U.S. Provisional Application No. 60/849,157, filed Oct. 3, 2006.

### BACKGROUND OF THE INVENTION

The instant invention relates to an improved electrode useful for modifying a substrate using corona or plasma treatment or coating a substrate using plasma enhanced chemical vapor deposition under atmospheric or near atmospheric pressure conditions.

Numerous prior art electrode configurations have been developed for atmospheric or near atmospheric pressure operation. The prior art configurations can be classified into two major types. The first type is intended to be used with a ground electrode positioned on the other side of the substrate from the working electrode. Examples of the first type of electrode are disclosed in WO 2006/049794 and WO 2006/049865. The second type uses a ground electrode position of the same side of the substrate as the working electrode. Examples of the second type of electrode are discussed in WO02/23960, U.S. Pat. No. 6,441,553 and U.S. Pat. No. 7,067,405.

Despite the significant advances provided by prior art electrodes, it would be an advance in the art if an electrode could be developed that permitted control of electric field intensity over a defined area, easily adjustable working gas velocity and flow characteristics and easy removal and replacement of the exposed working portion of the electrode.

### SUMMARY OF THE INVENTION

The instant invention is a solution to the above-mentioned problems. The electrodes of the instant invention permit control of electric field intensity over a defined area provide easily adjustable working gas velocity and flow characteristics and easy removal and replacement of the exposed working portion(s) of the electrode. More specifically, in one embodiment the instant invention is an improved electrode useful for modifying a substrate using corona or plasma treatment or coating a substrate using plasma enhanced chemical vapor deposition under atmospheric or near atmospheric pressure conditions, the electrode comprising a body defining at least a first cavity therein, the body having at least one inlet passageway therein in gaseous communication with the first cavity so that a gas mixture can be flowed into the first cavity by way of the at least one inlet passageway, the electrode having at least one outlet passageway in gaseous communication with the first cavity so that a gas that is flowed into the first cavity can flow out of the first cavity by way of the at least one outlet passageway, wherein the improvement comprises the at least one outlet passageway being a slot, the body comprised of at least a first removable portion thereof, one edge of the first removable portion defining one side of the at least one outlet passageway.

In another embodiment, the instant invention is an improved method for modifying a substrate by plasma or corona treatment or for coating a substrate using plasma enhanced chemical vapor deposition under atmospheric or near atmospheric pressure conditions wherein a gas is flowed from an electrode and into an electric field region adjacent the electrode, the electrode being defined by a body defining at least a first cavity therein, the body having at least one inlet passageway therein in gaseous communication with the first cavity so that a gas mixture can be flowed into the first cavity by way of the at least one inlet passageway, the electrode having at least one outlet passageway in gaseous communication with the first cavity so that a gas that is flowed into the first cavity can flow out of the first cavity by way of the at least one outlet passageway, wherein the improvement comprises controlling the temperature of the body.

### BRIEF DESCRIPTION OF THE DRAWINGS

FIG. 1 is a perspective view of an electrode body of a preferred embodiment of the instant invention;

FIG. 2 is a perspective view of a pair of removable electric field plate portions of a preferred embodiment of the instant invention;

FIG. 3 is a perspective view of the pair of removable electric field plate portions of FIG. 2 installed on the body of FIG. 1;

FIG. 4a, b, c and d show alternative cross section shapes for the removable electric field plate portions of FIG. 2; and

FIG. 5 shows a system for forming a plasma polymerized coating on a substrate using an electrode of the instant invention; and

FIG. 6 is an end view of another electrode embodiment of the instant invention.

### DETAILED DESCRIPTION

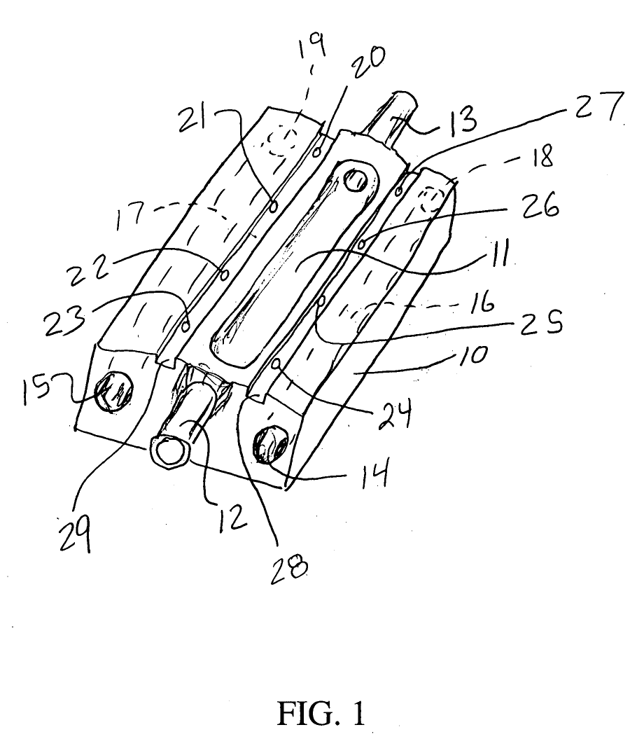

Referring now to FIG. 1, therein is shown a perspective view of an electrode body 10 of a preferred embodiment of the instant invention. The body 10 is made of metal and defines a first cavity 11 therein. The body 10 has a first inlet passageway 12, made of structural dielectric material, therein in gaseous communication with the cavity 11. The body 10 has a second inlet passageway 13, also made of structural dielectric material, therein in gaseous communication with the cavity 11. The body 10 also defines a second cavity 16 therein. The body 10 has an inlet 14 and outlet 18 each in fluid communication with the second cavity 16. The body 10 also defines a third cavity 17 therein. The body 10 has an inlet 15 and outlet 19 each in fluid communication with the third cavity 17. The body 10 defines a first channel 28 and a second channel 29 therein. Holes 20, 21, 22, 23, 24, 25, 26 and 27 are bored through the body 10 and into the channels 28 and 29 as shown.

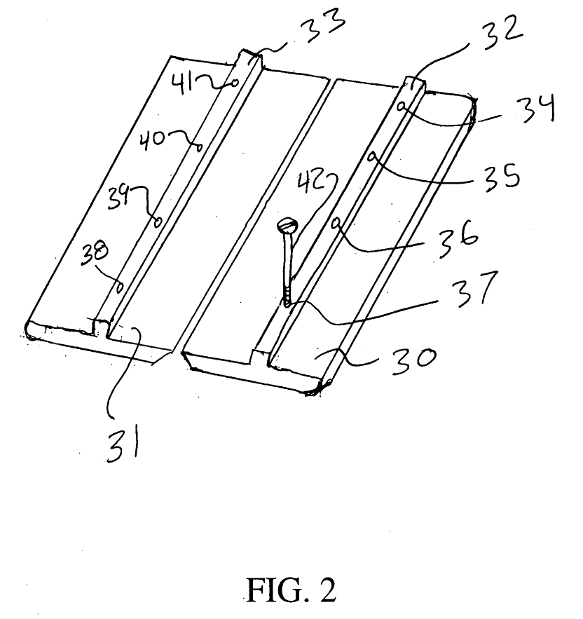

Referring now to FIG. 2, therein is shown a perspective view of a pair of removable aluminum electric field plate portions 30 and 31 of a preferred embodiment of the instant invention. Electric field plate portion 30 has a ridge portion 32 drilled and tapped to produce threaded holes 34, 35, 36 and 37. A threaded screw 42 is shown engaged in threaded hole 37. Electric field plate portion 31 has a ridge portion 33 drilled and tapped to produce threaded holes 38, 39, 40 and 41. The width of the ridge portions 32 and 33 is less than the width of the channels 28 and 29 of the body 10 shown in FIG. 1. The height of the ridge portions 32 and 33 is less than the depth of the channels 28 and 29 of the body 10 shown in FIG. 1.

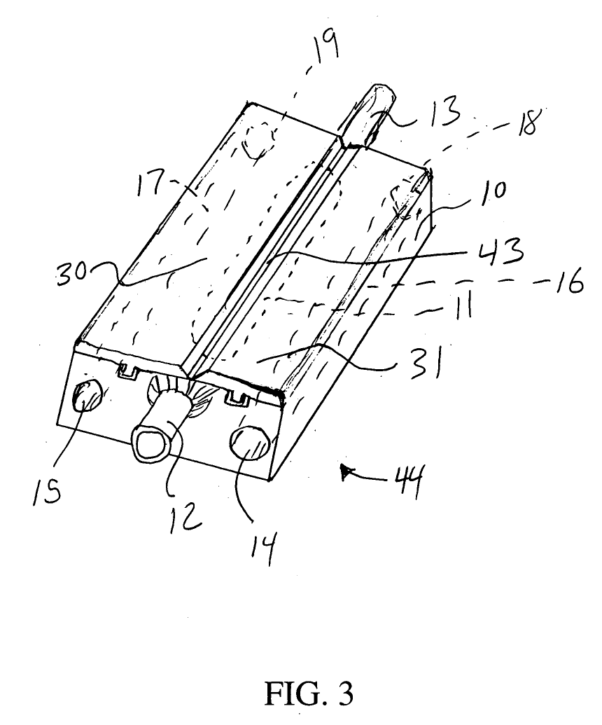

Referring now to FIG. 3, therein is shown a perspective view of the pair of removable electric field plate portions 30 and 31 of FIG. 2 installed on the body 10 of FIG. 1 by way of screws like the screw 42 shown in FIG. 2 inserted from the bottom of the body 10 through the holes 20, 21, 22, 23, 24, 25, 26 and 27 shown in FIG. 1 and engaging with the threaded holes 34, 35, 36, 37, 38, 39, 40 and 41 of the plate portions 30 and 31 shown in FIG. 2 to produce a preferred electrode 44 according to the instant invention. The plate portions 30 and 31 form a slot 43 so that when a gas is flowed into the cavity 11 by way of inlets 12 and 13, the gas flows out of the electrode 44 through the slot 43. A pair of feeler gauges of the same thickness are preferably inserted in each end of the slot 43 so that the width of the slot 43 can be established before tightening the screws that clamp the plate portions 30 and 31 to the body 10. The width of the slot 43 can thereby be adjusted from, for example and without limitation thereto, 0.001 inches to 0.050 inches. The width of the slot 43 is preferably adjusted to be relatively small, for example in the range of from 0.001 to 0.01 inches to minimize the consumption of working gas, to improve the evenness of the plasma polymerized coating and to optimize the quality of such coating. In operation a heated, cooled or temperature controlled fluid can be flowed into and out of the second and third cavities 16 and 17 by way of inlets 14 and 15 and outlets 18 and 19 to control the temperature of the electrode 44.

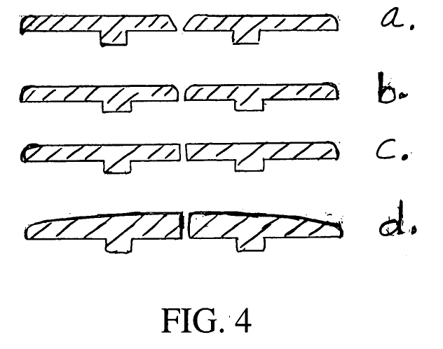

Referring now to FIG. 4a, b, c and d, therein is show a cross-sectional view of alternative shapes for the removable electric field plate portions 30 and 31 of FIG. 2. FIG. 4a shows a planar external surface and a chamfered edge. FIG. 4b shows a planar external surface and a rounded edge. FIG. 4c shows a planar external surface and a square edge. FIG. 4d shows a rounded external surface and a square edge. In many applications, the configuration shown in FIG. 4c is preferred. The shape of the edge influences the flow characteristics of working gas flowing from the slot towards the substrate to be coated. The shape of the external surface influences the electric field intensity over the exposed surface.

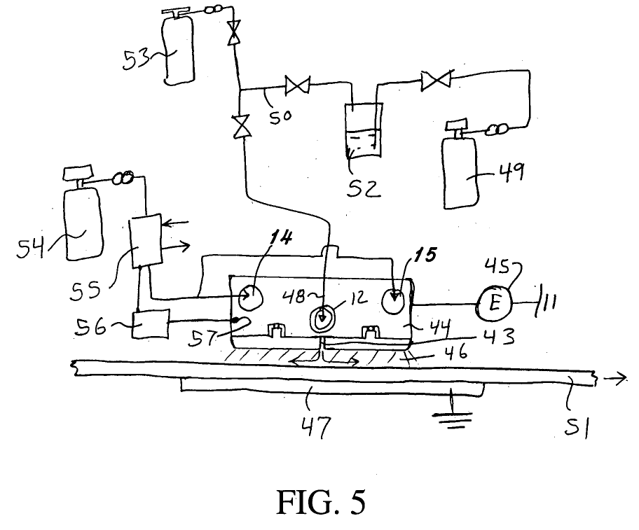

Referring now to FIG. 5, therein is shown a system for forming a plasma polymerized coating on a substrate using the electrode 44 of FIG. 3. The electrode 44 requires sufficient power and frequency via power source 45 to be applied to electrode 44 to create and maintain, for example and without limitation thereto, a corona discharge 46 in a spacing between the electrode 44 and a substrate 51 positioned on a counter electrode 47. The instant invention will operate between 0 watts and 20,000 watts. The operating frequency is between 0 Hz and 100 kHz. The maximum power to be delivered to the electrode should not exceed 50,000 watts. The maximum frequency for the instant invention can be in the tens of giga-hertz. Changing spatial dimensions will, of course, require changes to the operating ranges for power and frequency as is well understood in the art.

Referring still to FIG. 5, a mixture of gases 48 including a balance gas 53 and a working gas 50 is flowed into the inlet 12 the electrode 44 and then out the slot 43 to be plasma polymerized by the corona discharge 46 to form a coating onto the moving substrate 51. As used herein, the term “working gas” refers to a reactive substance, which may or may not be gaseous at standard temperature and pressure, that is capable of polymerizing to form a coating onto the substrate. As used herein, the term “balance gas” is reactive or non-reactive gas that carries the working gas through the electrode and ultimately to the substrate.

Examples of suitable working gases include organosilicon compounds such as silanes, siloxanes, and silazanes generated from the headspace of a contained volatile liquid 52 of such material and carried by a carrier gas 49 from the headspace and merged with balance gas 53 to form the mixture of gases 48. Examples of silanes include dimethoxydimethylsilane, methyltrimethoxysilane, tetramethoxysilane, methyltriethoxysilane, diethoxydimethylsilane, methyltriethoxysilane, triethoxyvinylsilane, tetraethoxysilane, dimethoxymethylphenylsilane, phenyltrimethoxysilane, 3-glycidoxypropyltrimethoxysilane, 3-methacrylpropyltrimethoxysilane, diethoxymethylphenylsilane, tris(2-methoxyethoxy)vinylsilane, phenyltriethoxysilane, and dimethoxydiphenylilane. Examples of siloxanes include tetramethyldisiloxane, hexamethyldisiloxane, octamethyltrisiloxane, and tetraethylorthosilicate. Examples of silazanes include hexamethylsilazanes and tetramethylsilazanes. Siloxanes are preferred working gases, with tetramethyldisiloxane being especially preferred.

The working gas is preferably diluted with a carrier gas 49 such as air or nitrogen before being merged with the balance gas. The v/v concentration of the working gas in the carrier gas is related to the vapor pressure of the working gas, and is preferably not less than 1%, more preferably not less than 5%, and most preferably not less than 10%; and preferably not greater than 50%, more preferably not greater than 30%, and most preferably not greater than 20%.

Examples of suitable balance gases include air, oxygen, nitrogen, helium, and argon, as well as combinations thereof. The flow rate of the balance gas is sufficiently high to drive the plasma polymerizing working gas to the substrate to form a contiguous film, as opposed to a powder. Preferably the flow rate of the balance gas is such that the velocity of the balance gas passing through the slot of at least 1000 feet per minute, more preferably at least 2000 feet per minute, and most preferably at least 4000 feet per minute; and preferably not greater than 10000 feet per minute, more preferably not greater than 8000 feet per minute, and most preferably not greater than 6000 feet per minute. Control of the relative flow rates of the balance gas and the working gas also contributes to the quality of the coating formed on the substrate. Preferably, the flow rates are adjusted such that v/v ratio of balance gas to working gas is at least 0.002%, more preferably at least 0.02%, and most preferably at least 0.2%; and preferably not greater than 10%, more preferably not greater than 6%, and most preferably not greater than 1%. The actual numeral values for gas injection speed, concentrations, and compositions depends, of course, on the type of coating that is being put down on the substrate as is well understood in the art. It should be understood that the use of the instant invention is not restricted to the above-mentioned values.

Although it is possible to carry out the process of the present by applying a vacuum or partial vacuum in, for example and without limitation thereto, the corona discharge region, (i.e, the region where the corona discharge is formed) the process is preferably carried out so that the corona discharge region is not subject to any vacuum or partial vacuum, that is, carried out at atmospheric or near atmospheric pressure.

The substrate to be coated or treated by the electrodes of the instant invention is not limited. Examples of substrates include, polyolefins such as polyethylene and polypropylene, polystyrenes, polycarbonates, and polyesters such as polyethylene terephthalate and polybutylene terephthalate.

Referring again to FIG. 5, temperature control gas 54 is flowed through heat exchanger 55 and into inlets 14 and 15. Thermister 57 embedded in the body of electrode 44 is connected to temperature control system 56. Temperature control system 56 controls heat exchanger 55 to control the temperature of the electrode 44. Preferably, the temperature of the electrode 44 is controlled to be in the range of from fifty to seventy degrees Celsius.

As discussed above, a flat or planar exterior surface is preferred for the electric field plates 30 and 31. A curved surface as shown in FIG. 4d increases the electric field in the plasma region near the slot and may be preferable in some applications. The electric field plates 30 and 31 are easily removable for cleaning, to change from a planar to a curved exposed surface and to change the shape of the slot.

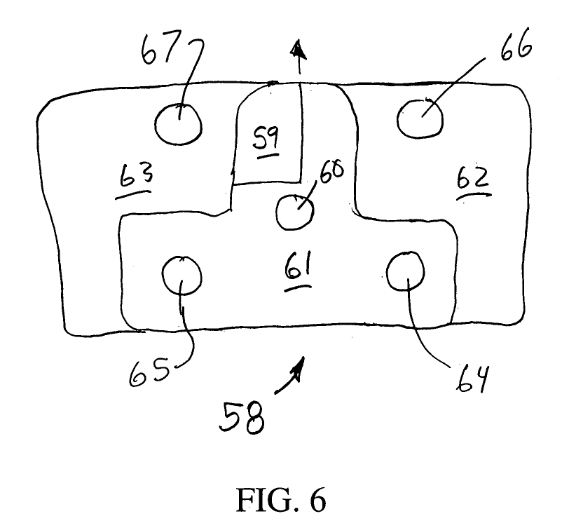

Referring now to FIG. 6, therein is shown an end view of another electrode 58 embodiment of the instant invention comprising an aluminum body 61 and a removable portion 59 bolted to the body 61. The body 61 has a working gas inlet 60 so that working gas can be flowed into a first cavity defined by body 61 and removable portion 59 and then flow from a slot defined by the gap between the portion 59 and the body 61. Dielectric portions 62 and 63 are attached to the body 61 and contain ground rods 66 and 67. When appropriately powered, a plasma generated by the electric field between the body 61 and portion 59 and the ground rods 66 and 67 is formed there between. Cooling inlets 64 and 65 are used in the same manner as the inlets 14 and 15 of the electrode 44 of FIG. 5. In the embodiment shown in FIG. 6, the slot width is not adjustable and is controlled by careful machining of the body 61 and/or the removable portion 59 that define the slot. Preferably the width of the slot is in the range of from 0.001 to 0.01 inches.

### CONCLUSION

In conclusion, it should be readily apparent that although the invention has been described above in relation with its preferred embodiments, it should be understood that the instant invention is not limited thereby but is intended to cover all alternatives, modifications and equivalents that are included within the scope of the invention as defined by the following claims.

1. An improved electrode useful for modifying a substrate using corona or plasma treatment or coating a substrate using plasma enhanced chemical vapor deposition under atmospheric or near atmospheric pressure conditions, the electrode comprising a body defining at least a first cavity therein, the body having at least one inlet passageway therein in gaseous communication with the first cavity so that a gas mixture can be flowed into the first cavity by way of the at least one inlet passageway, the electrode having at least one outlet passageway in gaseous communication with the first cavity so that a gas that is flowed into the first cavity can flow out of the first cavity by way of the at least one outlet passageway, wherein the improvement comprises the at least one outlet passageway being a slot, the body comprised of at least a first removable portion thereof, one edge of the first removable portion defining one side of the at least one outlet passageway.

2. The improved electrode of claim 1, wherein the exterior surface of the first removable portion is planar.

3. The improved electrode of claim 1, wherein the exterior surface of the first removable portion is curved.

4. The improved electrode of claim 1, wherein the improvement further comprises a second removable portion thereof, one edge of the second removable portion defining the other side of the at least one outlet passageway.

5. The improved electrode of claim 4, wherein the exterior surface of the first and second removable portions are planar.

6. The improved electrode of claim 4, wherein the exterior surface of the first and second removable portions are curved

7. The improved electrode of claim 1, wherein the improvement further comprises at least a second cavity in the body, the body having at least one inlet passageway therein in fluid communication with the second cavity and at least one outlet passageway therein in fluid communication with the second cavity so that a fluid can be flowed into and out of the second cavity to control the temperature of the body.

8. An improved method for modifying a substrate by plasma or corona treatment or for coating a substrate using plasma enhanced chemical vapor deposition under atmospheric or near atmospheric pressure conditions wherein a gas is flowed from an electrode and into an electric field region adjacent the electrode, the electrode being defined by a body defining at least a first cavity therein, the body having at least one inlet passageway therein in gaseous communication with the first cavity so that a gas mixture can be flowed into the first cavity by way of the at least one inlet passageway, the electrode having at least one outlet passageway in gaseous communication with the first cavity so that a gas that is flowed into the first cavity can flow out of the first cavity by way of the at least one outlet passageway, wherein the improvement comprises controlling the temperature of the body.

9. The improved method of claim 8, wherein the body defines a second cavity therein, the body having at least one inlet passageway therein in fluid communication with the second cavity and at least one outlet passageway therein in fluid communication with the second cavity so that a fluid can be flowed into and out of the second cavity to control the temperature of the body.
